(19) United States
(12) Patent Application Publication
(10) Pub. No.: US 2025/0362140 A1
(43) Pub. Date: Nov. 27, 2025

(54) APPARATUS, SYSTEM, AND METHOD FOR RECOMMENDING CHARGING STATION

(71) Applicant: HYUNDAI AUTOEVER CORP., Seoul (KR)

(72) Inventor: JaeSon Won, Seoul (KR)

(73) Assignee: HYUNDAI AUTOEVER CORP., Seoul (KR)

(21) Appl. No.: 19/213,651

(22) Filed: May 20, 2025

(30) Foreign Application Priority Data
May 22, 2024 (KR) 10-2024-0066741

(51) Int. Cl. G01C 21/34; B60L 53/62; B60L 53/66; B60L 53/68; G01C 21/36; G01R 31/3842

(52) U.S. Cl. CPC G01C 21/3469; B60L 53/62; B60L 53/665; B60L 53/68; G01C 21/3682; G01R 31/3842; B60L 2240/72

(57) ABSTRACT

A system includes a charging station recommendation apparatus configured to set a driving route that includes a charging station selected based on charging station recommendation information, based on a state of charge (SOC) of a battery of a vehicle. The system also includes a charging station information provision server configured to provide information on a plurality of charging stations located within a predetermined distance from a current driving route of the vehicle, in response to a request from the charging station recommendation apparatus. The system also includes a connected service server configured to recommend at least one charging station, among the plurality of charging stations, to the charging station recommendation apparatus.

### CROSS-REFERENCE TO RELATED APPLICATION

This application claims the benefit of and priority to Korean Patent Application No. 10-2024-0066741, filed on May 22, 2024, the entire contents of which are hereby incorporated herein by reference.

### BACKGROUND

### Technical Field

The present disclosure relates to an apparatus, system, and method for recommending a charging station, that enable a battery to be charged at a charging station.

### Description of the Background

In general, a navigation device included in a vehicle provides map information and provides guidance to a route up to a destination based on the map.

Such a navigation device also provides adjacent commercial facilities or road information based on a current location of a vehicle in addition to road guidance. For example, the navigation device may provide information, such as shops, restaurants, rest areas, gas stations, and charging stations on a route, and may provide road information regarding traffic jam, the occurrence of an accident, and a road construction.

In order for the vehicle to move to a charging station by using the navigation device, the charging station needs to be input to a route to the destination or stopover on the navigation device. However, it is very difficult for a user to add the location of the charging station to the route by checking the location of the charging station in advance.

If a charging station is encountered during driving, the vehicle may enter the charging station and perform charging. However, there is a problem in that it is not possible to determine in advance whether the charging station actually provides a charging service.

For example, the vehicle may check whether the charging station actually provides a charging service based on detailed information on the charging station, but there is a problem in that an actual charger is indicated as being capable of charging even though the actual charger has broken down because the accuracy of state information is low. Furthermore, if charging is impossible due to a compatibility problem of a charging plug or if a charging station does not operate normally due to an error of a payment system, the battery of the vehicle cannot be charged.

If a vehicle travels in order to search for another charging station in a situation in which the amount of remaining battery power is insufficient, a lot of time and efforts are required, and there may be a problem in that the battery of the vehicle is discharged before another charging station is found.

### SUMMARY

Various embodiments provide an apparatus, system, and method for recommending a charging station, that recommend a charging station that provides a charging service based on a state of charge (SOC) of a battery and set a route including the charging station.

In an embodiment, a system for recommending a charging station is provided. The system includes an apparatus for recommending a charging station, which is configured to set a driving route that passes through any one charging station included in charging station recommendation information or that has the charging station set as a destination based on a state of charge (SOC) of a battery, a charging station information provision server configured to provide information on a plurality of charging stations placed within a predetermined distance from the driving route in response to a request from the apparatus for recommending a charging station, and a connected service server configured to recommend at least one charging station, among the plurality of charging stations, to the apparatus for recommending a charging station.

In an embodiment, the charging station information provision server receives state information of each of the plurality of charging stations, including at least one of the location, name, number of chargers, and whether each charging station provides a charging service, in real time and transmits the state information to the apparatus for recommending a charging station.

In an embodiment, the connected service server calculates a chargeable index of the charging station for a charging success probability by checking whether charging in the charging station is successful based on data received from the apparatus for recommending a charging station.

In an embodiment, the apparatus for recommending a charging station displays the charging station information and state information received from the charging station information provision server, the charging station recommendation information received from the connected service server, and a chargeable index for a charging success probability on a map screen of a navigation device.

In an embodiment, the apparatus for recommending a charging station determines whether charging in the charging station is successful based on at least one of the amount of remaining battery power, a stay time at the charging station, whether a charging plug has been connected to a vehicle, whether power has been supplied to the battery, and whether a payment attempt has been made in the charging station.

In an embodiment, the apparatus for recommending a charging station transmits data regarding whether charging in the charging station is successful to the connected service server. The connected service server calculates a chargeable index of the charging station again based on data received from the apparatus for recommending a charging station.

In an embodiment, an apparatus for recommending a charging station includes a navigation device configured to provide guidance to a driving by setting a driving route up to a destination, and a processor configured to display charging station recommendation information including a chargeable index based on a state of charge (SOC) of a battery, configured to select any one charging station included in the charging station recommendation information, and configured to control the navigation device to pass through the charging station or to set the charging station as a destination.

In an embodiment, the navigation device receives information on a plurality of charging stations adjacent to the driving route and state information of the plurality of charging stations from the charging station information provision receives server, the charging station recommendation information and the chargeable indices from the connected service server, and displays locations of the plurality of charging stations in a map by matching the locations of the plurality of charging stations with the map.

In an embodiment, the processor selects a charging station included in the charging station recommendation information, among the plurality of charging stations, and displays the selected charging station on a map screen of the navigation device.

In an embodiment, the processor indicates a recommendation mark in the charging station included in the charging station recommendation information.

In an embodiment, the processor determines any one charging station, among the plurality of charging stations, in an autonomous driving mode or when a user command is not input within a predetermined time.

In an embodiment, the processor determines the charging station based on at least one of the charging station recommendation information, the chargeable index, a driving distance according to the SOC of the battery, a distance up to the charging station, state information of the charging station, and an expected driving distance and an expected arrival time including the charging station, with respect to each of the plurality of charging stations.

In an embodiment, the processor selects a charging station having a high chargeable index when a number of charging stations having an identical condition is plural.

In an embodiment, the processor generates charging data including whether charging in the charging station is successful and evaluation of the charging station and transmits the charging data to the charging station information provision server or the connected service server.

In an embodiment, a method of recommending a charging station includes controlling, by a processor, a navigation device to include a charging station in a driving route based on a state of charge (SOC) of a battery, searching for, by the navigation device, a charging station and receiving and displaying a plurality of charging stations and charging station recommendation information, selecting, by the processor, any one charging station, among the plurality of charging stations, based on the charging station recommendation information, setting, by the navigation device, a driving route including the selected charging station, and determining, by the processor, whether charging in the selected charging station is successful based on the SOC of the battery.

In an embodiment, the receiving and displaying of the plurality of charging stations and the charging station recommendation information includes receiving information on the plurality of charging stations adjacent to the driving route and state information of the plurality of charging stations from a charging station information provision server, receiving the charging station recommendation information and chargeable indices of the plurality of charging stations from a connected service server, and displaying the state information of the charging stations and the chargeable indices by matching locations of the plurality of charging stations with a map.

In an embodiment, in the receiving and displaying of the plurality of charging stations and the charging station recommendation information, the processor indicates a recommendation mark in a charging station included in the charging station recommendation information.

In an embodiment, in the selecting of the charging station, the processor determines any one charging station, among the plurality of charging stations, based on the charging station recommendation information in an autonomous driving mode or when a user command is not input within a predetermined time.

In an embodiment, tin the selecting of the charging station, the processor determines the charging station based on at least one of the charging station recommendation information, a chargeable index, a driving distance according to the SOC of the battery, a distance up to the charging station, state information of the charging station, and an expected driving distance and an expected arrival time including the charging station.

In an embodiment, in the determining of whether the charging in the selected charging station is successful, the processor determines whether the charging in the selected charging station is successful based on at least one of the amount of remaining battery power, a stay time at the selected charging station, whether a charging plug has been connected to a vehicle, whether power has been supplied to the battery, and whether a payment attempt has been made in the selected charging station.

According to aspects of the present disclosure, the apparatus, system, and method for recommending a charging station according to embodiments of the present disclosure can greatly increase the possibility that a battery can be charged by recommending a charging station based on a chargeable index that is determined based on whether charging in the charging station is successful.

The apparatus, system, and method for recommending a charging station according to embodiments of the present disclosure can reduce the time and efforts that are consumed to search for a charging station.

The apparatus, system, and method for recommending a charging station according to embodiments of the present disclosure can improve service quality by incorporating state information of a charging station in real time so that a charging service can be received from the charging station when a vehicle arrives at the charging station.

### BRIEF DESCRIPTION OF THE DRAWINGS

FIG. 1 is a block diagram illustrating components of a system for recommending a charging station according to an embodiment of the present disclosure.

FIG. 2 is a block diagram illustrating components of an apparatus for recommending a charging station according to an embodiment of the present disclosure.

FIG. 3 is a diagram illustrating a data flow of the system for recommending a charging station according to an embodiment of the present disclosure.

FIG. 4 is a diagram illustrating the results of searching for a driving route and a charging station by the apparatus for recommending a charging station according to an embodiment of the present disclosure.

FIG. 5 is a flowchart illustrating a method of recommending a charging station by the apparatus for recommending a charging station according to an embodiment of the present disclosure.

FIG. 6 is a flowchart illustrating a signal flow according to the recommendation of a charging station by the system for recommending a charging station according to an embodiment of the present disclosure.

### DETAILED DESCRIPTION

Hereinafter, embodiments of the present disclosure are described in detail with reference to the accompanying drawings.

The thicknesses of lines or the sizes of components illustrated in the accompanying drawings may have been exaggerated for the clarity of description and for convenience. Terms described below have been defined by taking into consideration their functions in the present disclosure, and may be changed depending on a user or operator's intention or practice. Accordingly, such terms should be defined based on the overall contents of this specification.

In the present disclosure, when a component, controller, device, element, apparatus, unit or the like of the present disclosure is described as having a purpose or performing an operation, function, or the like, the component, controller, device, element, apparatus, unit or the like should be considered herein as being “configured to” meet that purpose or to perform that operation or function. Each component, controller, device, element, apparatus, unit, server, gateway, and the like may separately embody or be included with a processor and a memory, such as a non-transitory computer readable media, as part of the apparatus.

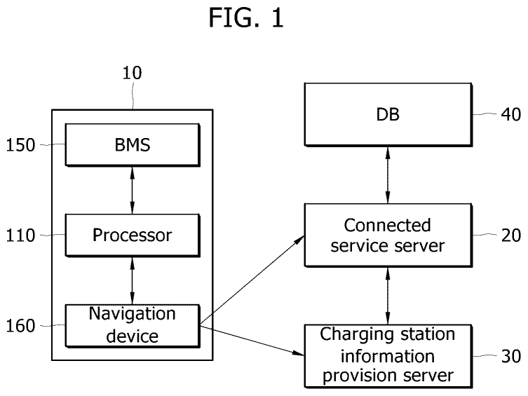

FIG. 1 is a block diagram illustrating components of a system for recommending a charging station according to an embodiment of the present disclosure.

Referring to FIG. 1, the system for recommending a charging station according to an embodiment of the present disclosure includes an apparatus 10 for recommending a charging station (also sometimes refers to herein as “charging station recommendation apparatus”), a connected service server 20, and a charging station information provision server 30.

Furthermore, the system for recommending a charging station may include a database (DB) 40.

Hereinafter, it is described that the connected service server 20 and the charging station information provision server 30 are divided and individually operate. However, the present disclosure is not limited thereto. For example, the connected service server 20 and the charging station information provision server 30 may be implemented with one server.

The apparatus 10 for recommending a charging station may be provided in a vehicle, and may receive charging station information through communication with the connected service server 20 and the charging station information provision server 30.

The charging station information provision server 30 may search for a plurality of charging stations within a predetermined distance from a driving route, may collect real-time state information of each charging station, and may transmit the real-time state information to the apparatus 10.

The connected service server 20 may recommend a charging station based on previously stored data. The connected service server 20 may generate a charging station recommendation list based on a chargeable index and charging station information stored in the DB 40, and may transmit the charging station recommendation list to the apparatus 10.

The connected service server 20 may recommend a charging station based on charging station information that is received from the charging station information provision server 30.

The apparatus 10 may include a processor 110 and a navigation device 160.

The processor 110 may check a state of charge (SOC) of a battery of the vehicle through a battery management system (BMS), and may perform control so that a charging station is included in a driving route of the navigation device 160 based on the SOC of the battery.

The processor 110 may control the navigation device 160 to display charging station information based on i) charging station information and real-time state information of one or more charging stations, that are received from the charging station information provision server 30 and ii) charging station recommendation information that is received from the connected service server 20.

The processor 110 may select at least one charging station that is adjacent to (e.g., is located along or near) a driving route of the vehicle, among a plurality of charging stations, based on charging station recommendation information and state information of the charging station, and may include the charging station in the driving route.

The processor 110 may calculate or otherwise determine a driving distance based on the SOC of the battery and may select a charging station located within the driving distance. The processor 110 may select, from among a plurality of charging stations, a charging station capable of starting charging within a predetermined time after the vehicle arrives at the charging station.

Furthermore, the processor 110 may select a charging station that operates normally, but may also display the state of the charging station by deactivating the state of the charging station or exclude the charging station when the state of the charging station cannot be known.

When a charging station is selected, the navigation device 160 may modify the driving route by searching for a route again so that the selected charging station is included in the driving route.

When a charging station is selected, the apparatus 10 may generate a driving route that passes through the selected charging station or has the selected charging station as a destination.

When a vehicle arrives at the selected charging station, the processor 110 may determine whether charging in the selected charging station is successful by comparing the SOC of the battery at an arrival time and the SOC of the battery at a departure time when the vehicle departs from the charging station, through the BMS.

The processor 110 may transmit charging data regarding a charging success or a charging failure to the connected service server 20.

The processor 110 may transmit charging data to the connected service server 20 by including information on a selected charging station, state information of the selected charging station, and user data regarding the charging station.

Although the apparatus 10 for recommending a charging station is generally described herein as operating on the basis of one processor 110, the present disclosure is not limited thereto. In some embodiments, a plurality of processors may distribute and process control operations for the selection of a charging station, control over a route, and the output of information on a charging station. In some embodiments, the apparatus 10 for recommending a charging station may be constituted with a charging station recommendation server.

In an embodiment, the processor 110 includes a plurality of processors (e.g., microprocessors). The processor 110 may include a first processor (not illustrated) that selects a charging station, from among a plurality of charging stations, based on received data and provides information of the selected charging station to the navigation device 160 so that the selected charging station is added to a route by the navigation device 160. The processor 110 may also include a second processor (not illustrated) that outputs received data and route information changed by the navigation device 160 and that determines whether charging in a selected charging station is successful.

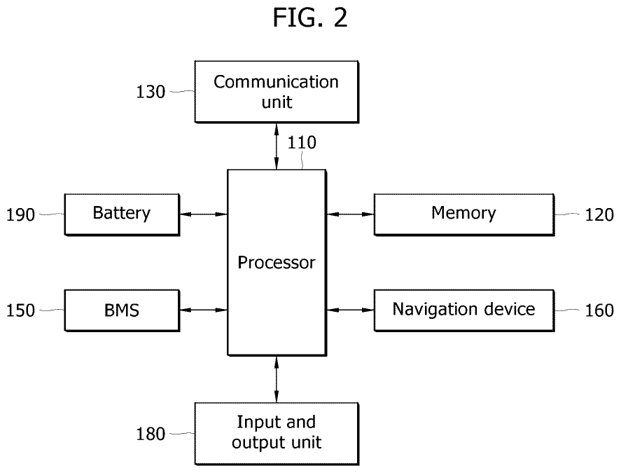

FIG. 2 is a block diagram illustrating components of the apparatus for recommending a charging station according to an embodiment of the present disclosure.

Referring to FIG. 2, the apparatus 10 for recommending a charging station includes the processor 110 and the navigation device 160 as described above.

Furthermore, the apparatus 10 for recommending a charging station may include an input and output unit 180, memory 120, and a communication unit 130.

The apparatus 10 for recommending a charging station may receive operating power from a battery 190 and may receive a state of charge (SOC) of the battery 190 from a battery management system (BMS) 150.

The BMS 150 monitors the state of a battery 190 and determines the SOC of the battery 190, for example by detecting a current and voltage of the battery 190. The BMS 150 may provide the SOC of the battery 190 to the processor 110.

The battery 190 stores electrical energy. The battery 190 may provide operating power to the apparatus 10 for recommending a charging station.

The navigation device 160 may provide map information, may set a driving route for driving up to a destination, may display the driving route on a screen, and may provide guidance for driving on the driving route through a voice device.

The memory 120 may store data, such as driving data, route data, road information data, and map data.

The memory 120 may also store charging station information, a chargeable index, charging station recommendation information, and state information of a charging station, that are received from the connected service server 20 and the charging station information provision server 30.

The memory 120 may store at least one of a route setting algorithm, a driving control algorithm, a battery management algorithm, a navigation device control algorithm, and a charging and discharging control algorithm.

The memory 120 may include nonvolatile memory, such as random access memory (RAM), ROM, and electrically erased programmable ROM (EEPROM), and/or storage means, such as flash memory.

The communication unit 130 may transmit data within the vehicle.

The communication unit 130 may receive a signal from an electric control unit (ECU) (not illustrated) of the vehicle, may provide the signal to the processor 110, and may transmit data based on a control command of the processor 110.

Furthermore, the communication unit 130 may transmit data to and receive data from at least one of another vehicle, a road facility, a control center, a terminal, a server, etc.

The communication unit 130 may transmit and receive data through any one of CAN communication and/or LIN communication within a vehicle. Furthermore, the communication unit 130 may perform communication through short-distance communication, such as Wi-Fi and Bluetooth, mobile communication, wireless access in vehicular environment (WAVE) for communication with a vehicle and a road facility, and vehicle to everything (V2X) for inter-vehicle communication.

The input and output unit 180 includes at least one piece of input means, among a switch, a button, and a touch pad, and may receive a user command therethrough.

The input and output unit 180 may provide a destination to the navigation device 160. The input and output unit 180 may also provide a route guidance command and another user command according to the selection of a charging station to the navigation device 160.

The input and output unit 180 includes at least one piece of output means, among a speaker, a buzzer, a lamp, and a display, and may output driving information, a driving route, and charging station information therethrough.

The input and output unit 180 may be used as input means and output means of the navigation device 160.

The input and output unit 180 may output driving information, may output map information, charging station information, a driving route, and charging station n recommendation information (or a recommendation list) through the navigation device 160, and may output at least one of a sound effect, voice guidance, and a state lamp based on a driving state.

When the vehicle breaks down, the input and output unit 180 may output at least one of a warning sound and a warning voice, and may output a guide message, a warning message, or a warning lamp.

The processor 110 may include at least one microprocessor. The processor 110 may operate based on data and algorithm data that are stored in the memory. For example, the processor 110 may be any one of an electric control unit (ECU), a vehicle control unit (VCU), and a main control unit (MCU).

The processor 110 may output a driving route or data regarding a charging station based on data that are received from the input and output unit 180 and/or the communication unit 130, may select a driving route or a charging station, and may transmit related data to the navigation device 160.

Furthermore, when the mode of a vehicle is set as an autonomous driving mode, the processor 110 may determine any one driving route or charging station even though a user command may not be input through the input and output unit 180.

When the battery 190 needs to be charged based on checking the SOC of the battery 190 through the BMS 150, the processor 110 may control the navigation device 160 to add a charging station to a route.

The navigation device 160 may change a driving route based on a control command of the processor 110 so that a charging station is added to a current driving route.

The navigation device 160 may request charging station information from the connected service server 20 and the charging station information provision server 30. In various embodiments, the processor 110 may request charging station information from the connected service server 20 or the charging station information provision server 30 through the communication unit 130.

The navigation device 160 may receive information on a charging station located within a predetermined distance from a current driving route, and may display the information on the charging station on a screen.

The processor 110 may display real-time state information, received from the charging station information provision server 30, regarding each of one or more charging stations, among a plurality of charging stations, and charging station recommendation information and a chargeable index received from the connected service server 20, on a screen.

When a charging station is selected through the input and output unit 180, the processor 110 may provide the data of the selected charging station to the navigation device 160.

Furthermore, the processor 110 may select any one charging station, among a plurality of charging stations.

The processor 110 may exclude a charging station whose current state cannot be checked based on real-time state information of the charging stations, and may then select at least one charging station by considering real-time state information and a chargeable index of the charging station based on the charging station recommendation information.

The processor 110 may calculate a driving distance based on the SOC of the battery 190 and may select a charging station located within the driving distance. Furthermore, the processor 110 may select a charging station by determining whether the charging station can start charging within a predetermined time after the vehicle arrives at the charging station based on a distance to the charging station.

Furthermore, if there are multiple charging stations having the same conditions, the processor 110 may select a charging station having a high chargeable index.

The processor 110 may provide data regarding a selected charging station to the navigation device 160 so that a route is set again by the navigation device 160.

The navigation device 160 may set a driving route including a selected charging station as a stopover or a destination.

The navigation device 160 may display charging station information on a screen by updating the charging station information based on data received from the charging station information provision server 30.

For example, when a vehicle arrives at a selected charging station, the processor 110 may check the SOC of the battery 190 based on an arrival time, and may determine whether charging in the selected charging station is successful based on a change in the amount of remaining power of the battery 190 by comparing the SOC of the battery 190 at the arrival time and the SOC of the battery 190 at a departure time when the vehicle departs from the selected charging station. The processor 110 may determine that charging in the selected charging station is successful when the amount of remaining power of the battery 190 is increased, and may determine that charging in the selected charging station has failed when the amount of remaining battery power is the same or reduced.

Furthermore, the processor 110 may determine that charging in the selected charging station is successful based on determining at least one i) that the vehicle has stayed at the charging station for a predetermined time or more, ii) that a charging plug has been connected to the vehicle, iii) that power has been supplied to the battery of the vehicle, and/or iv) that a charging fee for charging the battery has been paid. The processor 110 may determine that charging in the selected charging station has failed based on determining at least one i) that the vehicle has not stayed at the selected charging station for a predetermined time or more, ii) that a charging plug has not been connected to the vehicle, iii) that power has not been supplied to the battery of the vehicle, and/or iv) a payment attempt for charging the battery has not been made in the selected charging station.

The processor 110 may evaluate at least one of a quality of service, a payment method, a payment system, and a management state of a charging station based on user data that are received through the input and output unit 180, and may generate evaluation data of the charging station. Furthermore, the processor 110 may evaluate a charging station based on whether state information received from the charging station information provision server 30 and an actual state of the charging station are identical with each other by comparing the state information and the actual state.

The processor 110 may generate charging data, including at least one of information on a charging success or a charging failure, charging station information, and evaluation data of a charging station, and may cause the charging data to be transmitted to the connected service server 20.

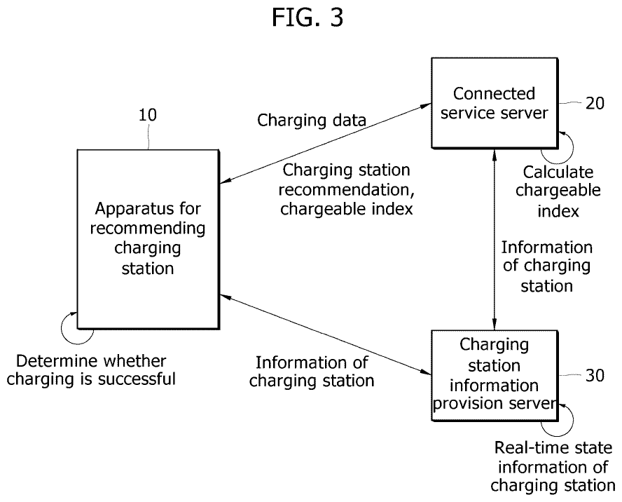

FIG. 3 is a diagram illustrating a data flow of the system for recommending a charging station according to an embodiment of the present disclosure.

Referring to FIG. 3, the apparatus 10 for recommending a charging station may communicate with the connected service server 20 and the charging station information provision server 30, and may collect data regarding a charging station.

The connected service server 20 may calculate or otherwise determine a chargeable index of each charging station, based on charging data that are received from the apparatus 10 and charging station information that is received from the charging station information provision server 30.

The connected service server 20 may determine whether a charging station included in a charging station recommendation list has been selected, may analyze a charging success by checking whether charging in the selected charging station is successful, and may calculate or otherwise determine a chargeable index by analyzing the cause of a failure when the charging fails.

Furthermore, the connected service server 20 may calculate or otherwise determine the chargeable index of the charging station again based on evaluation data included in the charging data.

The connected service server 20 may store data regarding charging station information and the chargeable index in the DB 40.

In an embodiment, the connected service server 20 may transmit the charging station information including the evaluation data to the charging station information provision server 30.

The connected service server 20 may generate charging station recommendation information (or a recommendation list) based on the chargeable index and the charging station information, and may transmit the charging station recommendation information and the chargeable index to the apparatus 10.

The connected service server 20 may generate the charging station recommendation information based on a plurality of charging stations that is received from the charging station information provision server 30. The charging station recommendation information may include a charging station recommendation list.

Furthermore, the connected service server 20 may set the priorities of a plurality of charging stations that is placed within a predetermined area, based on the chargeable index and the charging station information.

The charging station information provision server 30 may provide the apparatus 10 with information on a plurality of charging stations that are located in an area that includes a driving route, based on a location requested by the navigation device 160 of the apparatus 10 for recommending a charging station.

The charging station information provision server 30 may select one or more charging stations located within a predetermined distance from a driving route set in the navigation device 160, based on the driving route, and may provide charging station information of the selected one or more charging stations to the apparatus 10 for recommending a charging station. Furthermore, the charging station information provision server 30 may transmit the charging station information to the connected service server 20.

The charging station information provision server 30 may check real-time state information of each charging station among the one or more driving stations based on data received from the one or more of charging stations.

The charging station information provision server 30 may transmit data by including the real-time state information in the charging station information that is provided to the apparatus 10 for recommending a charging station.

The real-time state information may include at least one of the name of a charging station, the location of the charging station, the number of chargers included in the charging station, a charging station open state, a charging station parking fee, rate information, the type of charger, a chargeable socket type, the number of vehicles that are now being charged, an expected time until charging is completed, and a network state.

The apparatus 10 may display the received data through a map screen of the navigation device 160. The navigation device 160 may display at least one of the driving route, the charging station recommendation list, the state information of each charging station, and/or the chargeable index on the map screen. The apparatus 10 may display a recommendation mark with respect to a charging station included in the charging station recommendation list.

When a charging station, from among the one or more charging stations, is selected, the apparatus 10 generate a driving route including the selected charging station.

The apparatus 10 may transmit charging data according to whether charging in the selected charging station is successful to the connected service server 20. Furthermore, the apparatus 10 may transmit the evaluation data of the charging station to the charging station information provision server 30.

The connected service server 20 may calculate or otherwise determine the chargeable index of a corresponding charging station again based on received charging data, and may store the chargeable index in the DB 40.

Furthermore, the apparatus 10 may determine whether charging in the corresponding charging station is successful based on the SOC of the battery 190.

The charging station information provision server 30 may update state information of the corresponding charging station based on received evaluation data.

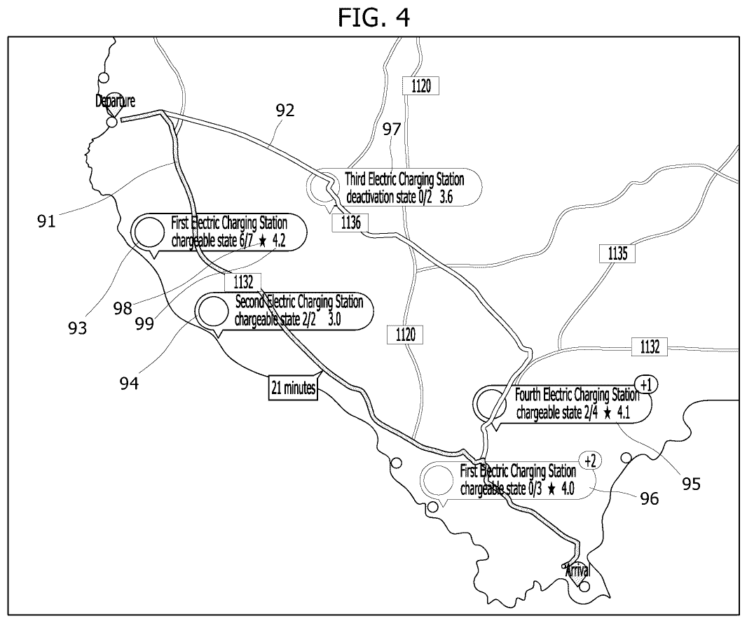

FIG. 4 is a diagram illustrating the results of searching for a driving route and a charging station by the apparatus for recommending a charging station according to an embodiment of the present disclosure.

Referring to FIG. 4, the navigation device 160 may display a driving route from a source to a destination on a screen.

The navigation device 160 may display a plurality of driving routes 91 and 92 on a screen.

The processor 110 may control the navigation device 160 based on the SOC of the battery 190 so that a charging station is included in the driving route.

The navigation device 160 may request search for a charging station from the charging station information provision server 30 and the connected service server 20.

The navigation device 160 may receive information on a plurality of charging stations and state information of the plurality of charging stations on the basis of the driving route from the charging station information provision server 30, and may display the information.

Furthermore, the navigation device 160 may receive charging station recommendation information and the chargeable index of each charging station from the connected service server 20.

The navigation device 160 may display charging station information along with the driving route.

The navigation device 160 may display the name and state information of each charging station by matching the location of each charging station included in the charging station information with a map. The state information may include the number of chargers and the charging state of each charging station indicating whether each charging station can provide a charging service.

For example, seven chargers have been installed in a first charging station 93 that is adjacent to the first driving route 91, and six chargers of the seven chargers are in a chargeable state. Two chargers have been installed in a second charging station 94 that is adjacent to the first driving route 91, and are in the chargeable state. Four chargers have been installed in a third charging station 95 that is adjacent to the second driving route 92, and two chargers of the four chargers are in the chargeable state.

All of the chargers in a fourth charging station 96 are performing charging and are in a non-chargeable state (i.e., the number of chargers in the chargeable state is 0). Accordingly, the state of all of the chargers in the fourth charging station 96 may be indicated as a deactivation state. The state of a fifth charging station 97 may be indicated as the deactivation state because state information of the fifth charging station 97 cannot be checked.

The processor 110 may indicate a charging station in the chargeable state and a charging station in the deactivation state with different colors. For example, the processor 110 may indicate a charging station in the chargeable state by blue, and may indicate a charging station in the non-chargeable state or a state information of which cannot be checked by gray.

The processor 110 may indicate a recommendation mark 98 in a charging station included in the charging station recommendation information based on the charging station recommendation information. The recommendation mark 98 may comprise a combination of one or more of text, special characters, an image, emoticon, etc. For example, a special letter having a star shape or a heart shape or an image may be used as the recommendation mark 98. Words, such as “RECOMMENDATION” or “BEST”, may be used as the recommendation mark 98.

In various embodiments, the processor 110 may display a recommendation list in any one area of a screen.

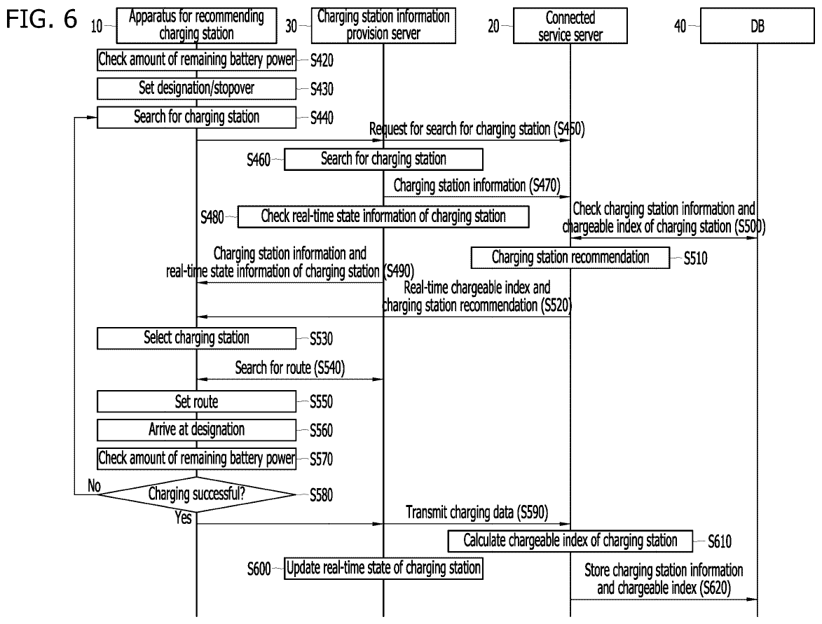

The processor 110 may display a chargeable index 99 obtained by indexing a charging success probability. The chargeable index 99 is illustrated in FIG. 6 as being indicated on a five-point scale. However, the present disclose is not limited thereto. For example, the chargeable index 99 may be indicated on a ten-point scale or a percentage (%), in some embodiments. Although he chargeable index 99 is illustrated in FIG. 6 as being indicated by a number, the present disclosure is not limited thereto. For example, the chargeable index 99 may be indicated as a combination of one or more of numbers, text, a special character, an image, and/or emoticon.

In an example, the chargeable index 99 may be indicated as 4.5 or 3.0, and/or may be indicated as 50%, 75%, or 95%.

In some embodiments, the processor 110 may display charging stations on a screen of the navigation device 160 based on charging station recommendation information of the connected service server 20 by excluding some of a plurality of charging stations included in the charging station recommendation information.

When a charging station, from among one or more charging stations displayed on a screen of the navigation device 160, is selected, the processor 110 may control the navigation device 160 to generate a driving route so that the driving route includes the selected charging station.

According an embodiment, if a charging station is not selected within a predetermined time or if the autonomous driving mode has been set, the processor 110 may select a charging station, from among of the one or more charging stations, without receiving a selection of a user.

The processor 110 may select a charging station based on at least one of charging station recommendation information, a chargeable index, a driving distance according to the SOC of a battery, a distance up to a charging station, state information of the charging station, and/or an expected driving distance and expected arrival time including a charging station.

For example, the processor 110 may select a charging station that is in the chargeable state, that corresponds to a recommended charging station, and that has a chargeable index equal to or greater than a predetermined value. If there are multiple charging stations having the same condition, the processor 110 may select a charging station having a high (e.g., a highest) chargeable index. Furthermore, the processor 110 may select a charging station having a close distance to the vehicle (e.g., a closest charging station), among a plurality of charging stations.

Accordingly, in an example, the processor 110 may control the navigation device 160 to generate a route that includes, or passes through, the first charging station 93.

After searching for a route including the first charging station 93 as a stopover or a destination, the navigation device 160 may reset the current driving route.

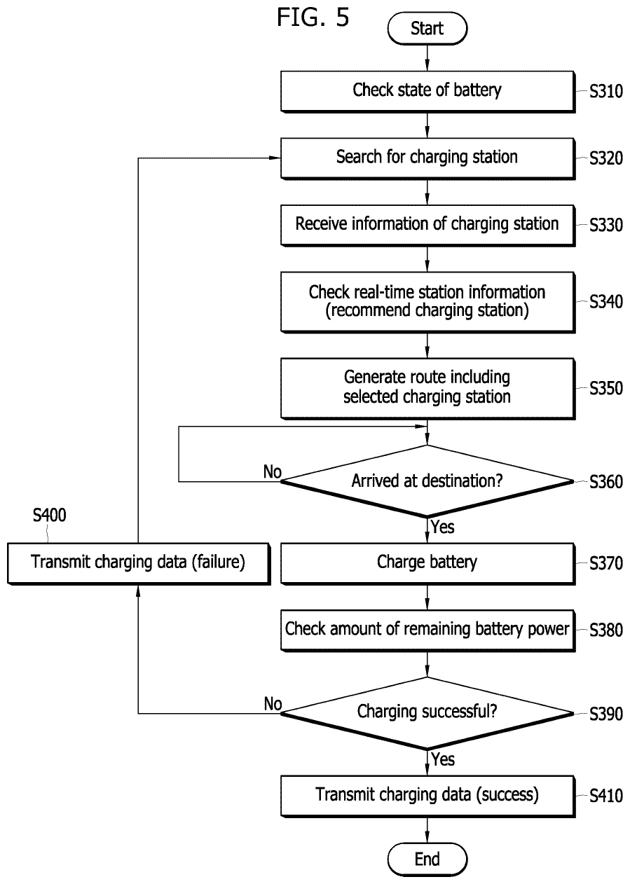

FIG. 5 is a flowchart illustrating a method of recommending a charging station by the apparatus for recommending a charging station according to an embodiment of the present disclosure.

Referring to FIG. 5, in an operation S310, the processor 110 of the apparatus 10 for recommending a charging station periodically checks the SOC of the battery 190 that is received from the BMS 150.

When the amount of remaining battery power of the battery is less than a set value, the processor 110 may set a vehicle to move to a charging station.

In an operation S320, the navigation device 160 searches for a charging station based on a control command of the processor 110. In an operation S330, the navigation device 160 may receive information on a retrieved charging station from at least one of the charging station information provision server 30 and/or the connected service server 20.

In an embodiment, the processor 110 may receive information on a charging station through the communication unit 130 and may transmit the information to the navigation device 160.

The navigation device 160 may receive charging station information and real-time state information from the charging station information provision server 30. Furthermore, the navigation device 160 may receive charging station recommendation information and a chargeable index from the connected service server 20.

In an operation S340, the navigation device 160 may check the state information of the charging station, and may display the charging station information, the state information, the chargeable index 99, and the recommendation mark 98 on a map screen on which a driving route is displayed by matching the location of the charging station with the map screen.

The processor 110 displays a plurality of charging stations received from the charging station information provision server 30 by matching the plurality of charging stations with a map, but may display the recommendation mark 98 when a charging station is a charging station included in the charging station recommendation information.

Furthermore, the processor 110 may control the navigation device 160 to display a charging station included in the charging station recommendation information of the connected service server 20, among the plurality of charging stations received from the charging station information provision server 30, by filtering the plurality of charging stations.

When a charging station, among the plurality of charging stations, is selected through the input and output unit 180, the processor 110 transmits information on the selected charging station to the navigation device 160.

Furthermore, the processor 110 may select a charging state, among the plurality of charging stations, without receiving a selection of a user in the autonomous driving mode or when a charging station is not selected within a predetermined time.

The processor 110 may control the navigation device 160 to set a driving route including the selected charging station.

In an operation S350, the navigation device 160 generates the driving route including the selected charging station as a stopover or a destination based on the location of the selected charging station.

When the vehicle arrives at the selected charging station as determined in an operation S360, the processor 110 checks the SOC of the battery 190 at the arrival time through the BMS 150.

Furthermore, when the vehicle arrives at the selected charging station, the processor 110 may check whether the selected charging station can provide a charging service by checking state information of the selected charging station again. If the selected charging station cannot provide a charging service, the processor 110 may check the remaining charging time of another vehicle and then wait, or may set the vehicle (e.g., control the vehicle or alert a driver of the vehicle) to move to another charging station.

In an operation S370, when the selected charging station is in the chargeable state, the processor 110 may generate a guidance message or voice guidance so that the battery of the vehicle is charged, and may output the guidance message or voice guidance through the input and output unit 180.

The processor 110 may check the charging of the battery by detecting whether a charger has been connected to the battery 190.

Furthermore, in an operation S390, when the location of the vehicle is changed after departing from the selected charging station, the processor 110 may check whether the battery 190 has been charged by checking the SOC of the battery 190 at the departure time.

Based on determining that the battery 190 has been charged based on a rate of change of the SOC of the battery 190 on the basis of the SOC of the battery 190, the processor 110 may determine that the charging is successful. Based on determining that the battery 190 has not been charged based on the rate of change of the SOC of the battery 190, the processor 110 may determine that the charging has failed.

In an operation S400, when the charging of the battery 190 in the selected charging station fails, the processor 110 may generate charging data regarding the failure of the charging and may transmit the charging data to the connected service server 20.

The processor 110 may then search for a charging station again, and may control the vehicle to move to a retrieved charging station and to charge the battery.

In an operation S410, if the battery 190 has been charged, the processor 110 may generate charging data regarding the success of the charging and transmit the charging data to the connected service server 20.

The connected service server 20 may calculate or otherwise determine a chargeable index of the charging station again based on the charging data received from the apparatus 10 for recommending a charging station.

Furthermore, the processor 110 may also transmit the charging data to the charging station information provision server 30. The charging station information provision server 30 may update the state information of the charging station based on the charging data.

FIG. 6 is a flowchart illustrating a signal flow of the system for recommending a charging station according to an embodiment of the present disclosure.

Referring to FIG. 6, the apparatus 10 for recommending a charging station may obtain information on a charging station through communicating with the charging station information provision server 30 and the connected service server 20, and may set a driving route that includes, or passes through, the charging station or has the charging station as a destination.

In an operation S420, the apparatus 10 checks the SOC of the battery 190 through the BMS 150. In an operation S430, the apparatus 10 sets a charging station to be added as a destination or a stopover when the amount of remaining power of the battery 190 is less than a set value.

In an operation S440, the navigation device 160 searches for a charging station to be added to the driving route.

In an operation S450, the navigation device 160 may request charging station information from the charging station information provision server 30 and the connected service server 20 based on a control command of the processor 110.

In response to the request, in an operation S460, the charging station information provision server 30 searches for a charging station placed within a predetermined distance based on the location of the apparatus 10 for recommending a charging station or a current driving route.

In an operation S470, the charging station information provision server 30 transmits the charging station information to the connected service server 20 based on the result of the search.

In an operation S480, the charging station information provision server 30 checks real-time state information of the retrieved charging station.

In an operation S490, the charging station information provision server 30 transmits charging station information and the real-time state information of the retrieved charging station to the apparatus 10 for recommending a charging station based on the results of the search.

The charging station information may include at least one of the location of the charging station, the name of the charging station, the number of chargers, a real-time SOC, and network connection information.

In an operation S500, the connected service server 20 receives the charging station information and a chargeable index from the DB 40 based on the charging station information.

In an operation S510, the connected service server 20 may generate charging station recommendation information in accordance with a charging station. For example, the connected service server 20 may select a recommended charging station based on at least one of a distance up to a charging station, a driving time, a chargeable index, and evaluation data of the charging station, and may generate charging station recommendation information including the recommended charging station.

In an operation S520, the connected service server 20 transmits a charging station recommendation list and a chargeable index to the apparatus 10 for recommending a charging station.

The apparatus 10 for recommending a charging station displays information on a plurality of charging stations that is received from the charging station information provision server 30 and the connected service server 20 on a map screen of the navigation device 160.

The apparatus 10 for recommending a charging station may display each charging station at each of a plurality of locations by matching the location of each charging station with a map, and may display whether each charging station provides a charging service, and state information, the recommendation mark 98, and the chargeable index 99 of each charging station.

A charging station, among the plurality of charging stations, is selected in an operation S530. In an operation S540, the apparatus 10 searches for a driving route to the selected charging station. In an operation S550, the apparatus 10sets a driving route that includes, or passes through, the selected charging station or that has the selected charging station as a destination.

When a vehicle moves along the driving route and arrives at the selected charging station as determining in an operation S560, the apparatus 10 may check the SOC of the battery 190 at the arrival time.

Furthermore, the apparatus 10 may check whether the selected charging station at which the vehicle has arrived is in the chargeable state.

When the selected charging station is in the chargeable state, the apparatus 10 may start the charging of the battery. If all of chargers in the selected charging station are in the non-chargeable state because other vehicles perform charging, the apparatus 10 may check a waiting time.

Furthermore, the apparatus 10 for recommending a charging station may search for a new charging station.

In an operation S570, when the charging of the battery is completed, the apparatus 10 for recommending a charging station checks the SOC of the battery on the basis of a charging completion time or a departure time. Furthermore, the apparatus 10 for recommending a charging station may check the time consumed for the charging by counting a stay time at the selected charging station.

In an operation S580, the apparatus 10 for recommending a charging station determines whether the charging in the charging station is successful by checking the amount of remaining power of the battery 190 based on the SOC of the battery 190.

When the stay time is a set time or more and a change of the SOC is equal to or greater than a set ratio, the apparatus 10 may determine that the charging is successful. When the stay time is less than the set time or the change of the SOC is less than the set ratio, the apparatus 10 may determine that the charging has failed.

Furthermore, the processor may determine whether the charging is successful based on at least one of whether a charging plug has been connected to the vehicle, whether power has been supplied to the battery, and whether a payment attempt has been made in the charging station.

When the charging fails, the apparatus 10 for recommending a charging station may search for a new charging station, and may repeat operations S440-S580 to attempt charging again after the vehicle moves. The apparatus 10 for recommending a charging station may generate charging data regarding the failure of the charging and transmit the charging data to the connected service server 20.

In an operation S590, when the charging is successful, the apparatus 10 may generate charging data regarding the success of the charging and transmit the charging data to the connected service server 20 or the charging station information provision server 30.

In an operation S600, the charging station information provision server 30 may update the state information of the charging station based on the charging data.

In an operation S610, the connected service server 20 may calculate the chargeable index of the charging station again based on the charging data. In an operation S620, the connected service server 20 stores the charging station information and the chargeable index in the DB 40.

Accordingly, the apparatus, system, and method for recommending a charging station according to aspects of the present disclosure may search for a charging station based on the SOC of the battery, and may add a retrieved charging station to a route. Accordingly, a vehicle can safely travel before the battery of the vehicle is discharged because the battery of the vehicle can be easily charged although the vehicle does not hunt for a charging station.

Furthermore, the apparatus, system, and method for recommending a charging station according to aspects of the present disclosure can easily select a charging station based on state information, a recommendation, and a chargeable index of the charging station, and can improve the charging success probability of a battery.

Although some embodiments of the disclosure are described above for illustrative purposes, those having ordinary skill in the art should appreciate that various modifications, additions and substitutions are possible, without departing from the scope and spirit of the disclosure as defined in the accompanying claims. Thus, the scope of the disclosure is defined by the accompanying claims and equivalents thereof.

What is claimed is:

1. A system comprising:
a charging station recommendation apparatus for a vehicle, the charging station recommendation apparatus configured to set a driving route that includes a charging station selected based on i) charging station recommendation information and ii) a state of charge (SOC) of a battery of the vehicle;
a charging station information provision server configured to provide, to the charging station recommendation apparatus, charging station information indicating a plurality of charging stations located within a predetermined distance from a current driving route of the vehicle, in response to a request from the charging station recommendation apparatus; and
a connected service server configured to provide the charging recommendation information station to the charging station recommendation apparatus, the charging station recommendation information recommending at least one charging station, among the plurality of charging stations, to the charging station recommendation apparatus.

2. The system of claim 1, wherein the charging station information provision server is configured to:
receive real-time state information of each of the plurality of charging stations, wherein the real-time state information for each charging station includes at least one of a location of the charging station, a name of the charging station, a number of chargers at the charging station, and whether each charger at the charging station provides a charging service; and
transmit the real-time state information to the charging station recommendation apparatus.

3. The system of claim 1, wherein the connected service server is configured to determine a chargeable index of the charging station by checking whether charging at the charging station is successful based on data received from the charging station recommendation apparatus, wherein the chargeable index indicates a charging success probability for the charging station.

4. The system of claim 1, wherein the charging station recommendation apparatus is configured to display, on a map screen of a navigation device, i) the charging station information and real-time state information received from the charging station information provision server and ii) the charging station recommendation information received from the connected service server, the charging station recommendation information including, for each of one or more charging stations indicated in the charging station information, a chargeable index indicating a charging success probability at the charging station.

5. The system of claim 1, wherein the charging station recommendation apparatus is configured to determine whether charging at the charging station is successful based on at least one of i) an amount of remaining power of the battery after the vehicle departs the charging station, ii) a stay time of the vehicle at the charging station, iii) whether a charging plug has been connected to the vehicle, iv) whether power has been supplied to the battery of the vehicle, or v) whether a payment attempt for charging the battery has been made in the charging station.

6. The system of claim 1, wherein:
the charging station recommendation apparatus is configured to transmit data regarding whether charging at the charging station is successful to the connected service server; and
the connected service server is configured to update a chargeable index of the charging station based on the data received from the recommendation apparatus.

7. An apparatus for recommending a charging station, the apparatus comprising:
a navigation device configured to provide guidance for driving a vehicle; and
a processor configured to:
display charging station recommendation information including a chargeable index based on a state of charge (SOC) of a battery of the vehicle,
select a charging station included in charging station recommendation information, and
control the navigation device to generate a driving route that includes the charging station or to set the charging station as a destination for the vehicle.

8. The apparatus of claim 7, wherein the navigation device is configured to:
receive, from a charging station information provision server, i) charging station information on a plurality of charging stations within a predetermined distance from a current driving route of the vehicle and ii) state information of the plurality of charging stations;
receive, from a connected service server, charging station recommendation information including chargeable indices; and
display locations of the plurality of charging stations in a map by matching the locations of the plurality of charging stations with the map.

9. The apparatus of claim 8, wherein the processor is configured to:
select a charging station, among the plurality of charging stations included in the charging station recommendation information; and
display the selected charging station on a map screen of the navigation device.

10. The apparatus of claim 8, wherein the processor is configured to indicate a recommendation mark in a charging station included in the charging station recommendation information.

11. The apparatus of claim 8, wherein the processor is configured to determine a charging station, among the plurality of charging stations without receiving a selection of a user, in an autonomous driving mode or when a user command is not input within a predetermined time.

12. The apparatus of claim 11, wherein the processor is configured to determine the charging station based on at least one of the charging station recommendation information, the chargeable index, a driving distance according to the SOC of the battery, a distance up to the charging station, state information of the charging station, and an expected driving distance and an expected arrival time comprising the charging station, with respect to each of the plurality of charging stations.

13. The apparatus of claim 7, wherein the processor is configured to, based on determining that multiple charging stations, among a plurality of charging stations included in the charging station recommendation information, have an identical condition, select a charging station based on a chargeable index.

14. The apparatus of claim 9, wherein the processor is configured to:
generate charging data including indication of whether charging at the charging station is successful and evaluation of the charging station; and
transmit the charging data to one or both of the charging station information provision server or the connected service server.

15. A method of recommending a charging station, the method comprising:
controlling, by a processor, a navigation device of a vehicle to include a charging station in a driving route based on a state of charge (SOC) of a battery of the vehicle;
receiving and displaying, by the navigation device, charging station information for a plurality of charging stations and charging station recommendation information;
selecting, by the processor, a charging station, among the plurality of charging stations, based on the charging station recommendation information;
setting, by the navigation device, the driving route including the selected charging station; and
determining, by the processor, whether charging at the selected charging station is successful based on the SOC of the battery.

16. The method of claim 15, wherein receiving and displaying the charging station information of the plurality of charging stations and the charging station recommendation information includes:
receiving, from a charging station information provision server, i) the charging station information on the plurality of charging stations within a predetermined distance from a current driving route of the vehicle and ii) state information of the plurality of charging stations;
receiving, from a connected service server, the charging station recommendation information and chargeable indices of the plurality of charging stations; and
displaying the state information of the plurality of charging stations and the chargeable indices by matching locations of the plurality of charging stations with a map.

17. The method of claim 16, wherein receiving and displaying the charging station information of the plurality of charging stations and the charging station recommendation information includes displaying a recommendation mark in a charging station, and wherein the recommendation mark is determined based on the charging station recommendation information.

18. The method of claim 15, wherein selecting the charging station includes selecting the charging station based on the charging station recommendation information without receiving a selection of a user in an autonomous driving mode or when a user command is not input within a predetermined time.

19. The method of claim 15, wherein selecting the charging station includes selecting the charging station based on at least one of i) the charging station recommendation information, a chargeable index, ii) a driving distance according to the SOC of the battery, iii) a distance up to the charging station, iv) state information of the charging station, or v) an expected driving distance and an expected arrival time comprising the charging station.

20. The method of claim 15, wherein determining whether the charging at the selected charging station is successful includes determining whether the charging at the selected charging station is successful based on at least one of i) an amount of remaining power of the battery after the vehicle departs the charging station, ii) a stay time of the vehicle at the selected charging station, iii) whether a charging plug has been connected to the vehicle, iv) whether power has been supplied to the battery of the vehicle, or v) whether a payment attempt for charging the battery has been made in the selected charging station.
